(19) United States
(12) Patent Application Publication
(10) Pub. No.: US 2024/0291437 A1
(43) Pub. Date: Aug. 29, 2024

(54) DOHERTY POWER AMPLIFIER

(71) Applicant: Ampleon Netherlands B.V., Nijmegen (NL)

(72) Inventors: Yang Yang, Nijmegen (NL); Jiandong Jin, Shanghai (CN); Binghui Zhang, Zhejiang (CN)

(21) Appl. No.: 18/573,278

(22) PCT Filed: Jun. 21, 2022
(86) PCT No.: PCT/NL2022/050352

§ 371 Date: Dec. 21, 2023

(30) Foreign Application Priority Data
Jun. 24, 2021 (NL) 2028527

(51) Int. Cl. H03F 1/02; H01L 23/66; H03F 1/56; H03F 3/24

(52) U.S. Cl. CPC H03F 1/0288; H01L 23/66; H03F 1/565; H03F 3/245; H01L 2223/6611; H01L 2223/6655; H03F 2200/451

(57) ABSTRACT

The present invention relates to a Doherty power amplifier, and a Doherty power amplifier module configured to be mounted on a printed circuit board for forming such a Doherty power amplifier. According to the present invention, a series network of a shunt inductor and shunt DC decoupling capacitor is used to partially resonate out the output capacitance of the main transistor. In addition, a series inductor is connected in between the output of the main transistor and the combining node, and a shunt capacitive element is connected in between the combining node and ground. The part of the output capacitance that is not resonated out, the series inductor, and the shunt capacitive element form a lumped equivalent of a 90 degrees transmission line at the fundamental frequency.

The present invention relates to a Doherty power amplifier and to a Doherty power amplifier module configured to be mounted on a printed circuit board for forming such a Doherty power amplifier. The Doherty power amplifier architecture of the present invention is particularly well suited for application in 5G massive Multiple Input Multiple Output, MIMO, systems.

Doherty Power Amplifiers, DPAs, are well known in the art. These amplifiers typically comprise a main amplifier and one or more peak amplifiers. The one or more peak amplifiers are typically biased in class C, whereas the main amplifier is biased in class AB or B.

Under low input power conditions, only the main amplifier is on. Under high input power conditions, the main amplifier and the one or more peak amplifiers are all on.

The main amplifier is connected to the one or more peak amplifiers through one or more impedance inverters. As a result of these impedance inverters, the load seen by the main amplifier is modulated by the one or more peak amplifiers to such an extent that this load is higher under low input power conditions than under high input power conditions. This load modulation improves the efficiency of the DPA under low input power conditions.

The Si laterally diffused metal-oxide-semiconductor, LDMOS, DPA is widely used in 4G communication systems. However, as requirements for the operational frequency, bandwidth, and efficiency of the DPA have increased for 5G communication systems, DPAs made with new technologies are introduced to improve performance to meet these new requirements.

Recently, Gallium Nitride, GaN, has emerged as a promising material system for power amplifiers, especially at higher frequencies>1 GHz. Furthermore, for amplifiers realized in this material system, it is known that the performance of these amplifiers is particularly sensitive to the impedances presented to the main amplifier and the one or more peak amplifiers at the harmonic frequencies. More in particularly, benefitting from its higher power density and higher Ft, GaN-based power amplifiers using high electron mobility transistors, HEMTs, are able to demonstrate high performance by optimizing the harmonic impedances that are presented at the input and output of the main amplifier and the one or more peak amplifiers.

The 5G communication systems use a modulated signal, which means that the power amplifier needs to work under power back-off. Normally, the power amplifier needs to operate at 8.5-9 dB back-off from full saturated power, thereby reducing the efficiency.

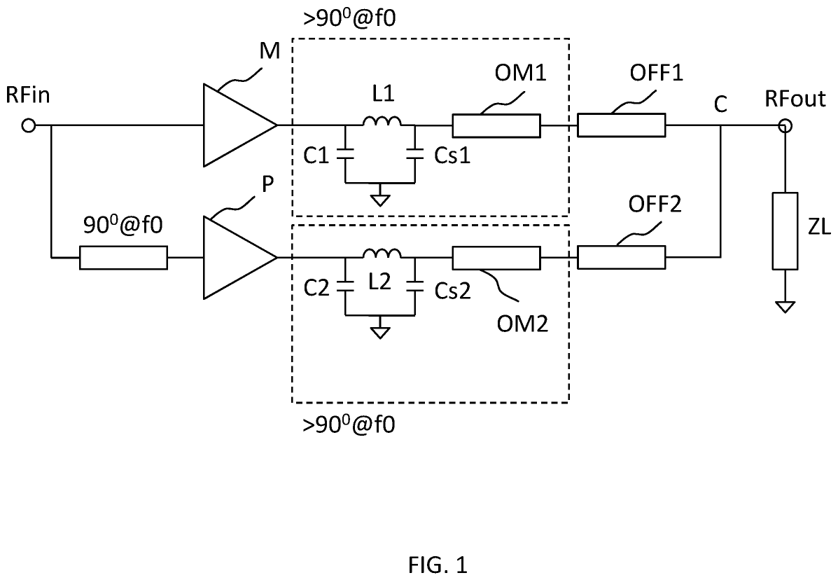

A known DPA architecture used for Si LDMOS transistors is shown in FIG. 1. In this architecture, an input signal provided at an input terminal RFin is split in a component for main amplifier M and a component for peak amplifier P. Compared to the signal provided to main amplifier M, the signal provided to peak amplifier P is delayed by approximately 90 degrees at an operational frequency of the DPA.

Main amplifier M and peak amplifier P have an output capacitance C1 and C2, respectively. The harmonic impedances presented at the output of main amplifier M and peak amplifier P can be regulated using a low-pass network comprising a series inductor and a shunt capacitor. For main amplifier M, this network is formed using L1 and Cs1, and for peak amplifier P, this network is formed using L2 and Cs2. This low-pass network changes the impedance presented at the fundamental frequency. To mitigate this effect, output matching networks OM1 and OM2 are used for main amplifier M and peak amplifier P, respectively.

The combined phase delay of the output matching network and the low-pass network exceeds 90 degrees at the fundamental frequency. To still obtain Doherty operation, a phase delay unit OFF1, OFF2 is used that provides a different phase delay for main amplifier M and peak amplifier P. More in particular, the combined phase delay of the low-pass network, OM1, and OFF1, is 270 degrees at the fundamental frequency, whereas the combined phase delay of the low-pass network, OM2, and OFF2, is 180 degrees at the fundamental frequency. These combined phase delays allow the signals amplified by main amplifier M and peak amplifier P to arrive in-phase at combining node C. This latter node is connected, directly or indirectly via impedance matching networks, to a load ZL that is connected to output terminal RFout.

A problem associated with the architecture of FIG. 1 is related to phase delay units OFF1 and OFF2. As a result of the phase delay these units need to provide, they occupy a relatively large amount of space. This prevents a compact realization of the Doherty power amplifier and limits the bandwidth of the amplifier.

An object of the present invention is to provide a compact Doherty power amplifier architecture in which GaN HEMTs can be used and which architecture is able to provide improved efficiencies at power back-off.

This object is achieved using a Doherty power amplifier as defined in claim 1. According to the present invention, the Doherty power amplifier comprises an output terminal that is connectable or connected to a load, a main transistor having a first output capacitance, and a peak transistor having a second output capacitance. The DPA further comprises a first shunt network arranged in between an output of the main transistor and ground, the first shunt network comprising a series connection of a first shunt inductor and a first shunt DC decoupling capacitor.

Within the context of the present invention, when a component is connected to ground, this component is connected to electrical ground during operation. Small voltage drops may exist between this component and the true electrical ground, for example due to parasitic inductances or resistances. Despite these voltage drops, the component is still considered to be connected to ground within the context of the present invention.

The DPA further comprises a first series inductor arranged in between the output of the main transistor and a combining node, wherein the combining node is electrically connected to the output terminal either directly or indirectly via an impedance matching network. The Doherty power amplifier is configured to combine signals amplified by the main transistor and the peak transistor at the combining node. Furthermore, the DPA additionally comprises a first shunt capacitive element arranged in between the combining node and ground.

According to the present invention, an inductance of the first shunt network is configured such that the first shunt network resonates with a part of the first output capacitance at a given frequency within an operational frequency band of the Doherty power amplifier. Furthermore, a remaining part of the first output capacitance forms, together with the first series inductor and at least a part of the first shunt capacitive element, an impedance inverter at said given frequency.

According to the present invention, the first series inductor and the first shunt capacitive element form a low-pass network similar to that shown in FIG. 1. This network allows control of the impedance at the harmonic frequencies. At the same time, these same components are used for realizing an impedance inverter to obtain Doherty operation. Consequently, the same components are used for different purposes, thereby reducing the space that is required for realizing the architecture of the invention.

The impedance inverter can be a first lumped equivalent of a transmission line having an electrical length of substantially 90 degrees at said given frequency.

The DPA may further comprise a second shunt network arranged in between an output of the peak transistor and ground. This second shunt network comprises a series connection of a second shunt inductor and a second shunt DC decoupling capacitor. The DPA may additionally comprise a second series inductor arranged in between the output of the peak transistor and an intermediate node, and a phase delay unit connected in between the intermediate node and the combining node. The DPA may further comprise a second shunt capacitive element arranged in between the intermediate node and ground.

An inductance of the second shunt network can be configured such that the second shunt network resonates with a part of the second output capacitance at said given frequency, wherein a remaining part of the second output capacitance forms, together with the second series inductor and the second shunt capacitive element, a second lumped equivalent of a transmission line. A combined phase delay associated with the second lumped equivalent and the phase delay unit substantially equals 180 degrees at said given frequency. For example, the second lumped equivalent may be a lumped equivalent of a transmission line having an electrical length of substantially 90 degrees at said given frequency.

The phase delay unit may comprise a third series inductor that is arranged in between the intermediate node and the combining node, a third shunt capacitive element arranged in between the combining node and ground, and a fourth shunt capacitive element arranged in between the intermediate node and ground. Furthermore, the third shunt capacitive element and the first shunt capacitive element can be embodied as a single shunt capacitor, and/or the fourth shunt capacitive element and the second shunt capacitive element can be embodied as a single shunt capacitor.

In other embodiments, the first shunt capacitive element is at least partially formed by the second output capacitance. In even other embodiments, a part of the second output capacitance may form the first shunt capacitive element. For these embodiments, the combining node can be indirectly connected to the output terminal using an impedance matching network that comprises a third shunt network connected in between the combining node and ground and a series impedance matching network arranged in between the combining node and the output terminal. Furthermore, to tune the impedance seen by the peak transistor at the harmonic frequencies, the third shunt matching network may comprise a third shunt capacitor arranged in between the combining node and ground, and/or a third shunt network arranged in between the combining node and ground, the third shunt network comprising a series connection of a third shunt inductor and a third shunt DC decoupling capacitor.

The DPA may further comprise a first low-pass input impedance matching network connected to an input of the main transistor and a second low-pass input impedance matching network connected to an input of the peak transistor. The first and second low-pass input impedance matching networks may each comprise one or more matching stages, each matching stage comprising a shunt inductor and a series inductor. The Applicant has found by using low-pass matching stages at the inputs of the main and peak transistors, in particular two or more stages per transistor, the sensitivity of the main and peak transistor for the phase of the second harmonic impedance at the output of the main and peak transistor is reduced.

The DPA may further comprise an input terminal, and a splitter configured for splitting an RF signal received at the input terminal into a first component to be fed to the main transistor and a second component to be fed to the peak transistor.

The main transistor and the peak transistor may each comprise a Gallium Nitride based high electron mobility transistor. However, the present invention could equally be used for Si LDMOS transistors.

The DPA may comprise a printer circuit board, and a packaged Doherty power amplifier module mounted on the printed circuit board, wherein the module comprises a substrate, a first active semiconductor die mounted on the substrate and on which the main transistor is integrated, and a second active semiconductor die mounted on the substrate and on which the peak transistor is integrated.

The module may correspond to a flat no-leads package, such as a dual flat no-leads package, DFN, or a quad flat no-leads package, QFN, wherein the substrate is formed by a conductive central pad that is exposed on a backside of the package, and wherein the module further comprises a plurality of pads that are spaced apart from the central pad and that are exposed on the backside of the package. The present invention is however not limited to flat no-leads packages. For example, the substrate may be in the form of a laminate or further printed circuit board instead of a metal central pad. In such case, the further printed circuit board or laminate may be provided with a ball grid array or land grid array on its backside for allowing electrical connection between the module and the printed circuit board on which the module is mounted. In even other embodiments, lead frame packages are used in which the substrate is a conductive substrate, and wherein a plurality of leads are used for electrically connecting the module to the printed circuit board on which the module is arranged. The module may comprise a lid or cover for protecting the components inside the module. This lid or cover may be formed using a solidified molding compound. In even other embodiments, the solidified molding compound encapsulates the components.

The module may comprise one or more first passive dies on which a first impedance matching network is integrated of which an output is connected to an input of the main transistor, and on which a second impedance matching network is integrated of which an output is connected to an input of the peak transistor. The first impedance matching network may correspond to the abovementioned first low-pass input matching network, and the second impedance matching network may correspond to the abovementioned second low-pass input matching network. The first impedance matching network and the second impedance matching network may be arranged on separate first passive dies or on a single first passive die.

The first shunt inductor and the first shunt DC decoupling capacitor can be integrated on the printed circuit board, and/or wherein, if applicable, the second shunt inductor and the second shunt DC decoupling capacitor can be integrated on the printed circuit board.

The module may comprise one or more second passive dies on which the first shunt inductor and the first shunt DC decoupling capacitor are integrated, and/or, if applicable, on which the second shunt inductor and the second shunt DC decoupling capacitor are integrated. The first shunt inductor and the first shunt DC decoupling capacitor can be arranged on a same second passive die. In other embodiments, the first shunt inductor and the first DC decoupling capacitor may be arranged on different second passive dies. Among these second passive dies, the passive die on which the first shunt inductor is arranged can be a ceramic die whereas the passive die on which the first shunt DC decoupling capacitor can be Si passive die. Similar considerations hold for the second shunt DC decoupling capacitor and the second shunt inductor.

The DPA may further comprise a first transmission line or lumped equivalent thereof integrated on or formed on the printed circuit board, the first transmission line forming at least a part of the first series inductor, wherein the first shunt capacitive element is integrated on or formed on the printed circuit board. For example, the first shunt capacitive element can be a discrete capacitor. Additionally or alternatively, the DPA ma further comprise, if applicable, a second transmission line or lumped equivalent thereof integrated on or formed on the printed circuit board, the second transmission line forming at least a part of the second series inductor, wherein the second shunt capacitive element is integrated on or formed on the printed circuit board.

The DPA may further comprise a third passive die on which the phase delay unit is integrated, the phase delay unit comprising a transmission line or lumped equivalent thereof, the third passive die preferably comprising an impedance matching network connected between the combining node and the output terminal. The lumped equivalent may for example comprise a shunt capacitor-series inductor-shunt capacitor network. In this lumped equivalent, the series inductor can be formed using one or more bondwires extending between the shunt capacitors.

The first series inductor may be formed using one or more bondwires between the output of the main transistor and a terminal of phase delay unit, and/or the second series inductor may be formed using one or more bondwires between the output of the peak transistor and an other terminal of phase delay unit. In this case, the first shunt capacitive element and the abovementioned shunt capacitor of the phase delay unit can be combined into a single capacitor integrated on the third passive die. Similar considerations hold for the second shunt capacitive element.

For the embodiments in which the second shunt capacitive element is at least partially formed by the second output capacitance or wherein a part of the second output capacitance forms the second shunt capacitive element, the DPA may further comprise a fourth passive die on which a part of the first series inductor is formed. Alternatively, the DPA may comprise one or more bondwires extending between the output of main transistor and the peak transistor for forming the first series inductor. In both cases, the DPA may further comprise a fifth passive die on which the third shunt capacitor and/or the series impedance matching network is arranged. Alternatively, the third shunt capacitor can be arranged on the printed circuit board. Additionally or alternatively, the third shunt network may be integrated or formed on the printed circuit board.

The abovementioned splitter can be integrated or formed on the printed circuit board.

The DPA may comprise a main driver stage arranged in between the splitter and the main transistor and preferably on the substrate, the main driver stage being configured for amplifying the signal to be fed to the main transistor and for providing this amplified signal to the main transistor. Additionally or alternatively, the DPA may comprise a peak driver stage arranged in between the splitter and the peak transistor and preferably on the substrate, the peak driver stage being configured for amplifying the signal to be fed to the peak transistor and for providing this amplified signal to the peak transistor.

According to a second aspect, the present invention provides a packaged Doherty power amplifier module as described above and that is configured to be mounted on a printed circuit board for forming the Doherty power amplifier as described above.

Next, the present invention will be described in more detail referring to the appended drawings, wherein:

FIG. 1 illustrates a known DPA;

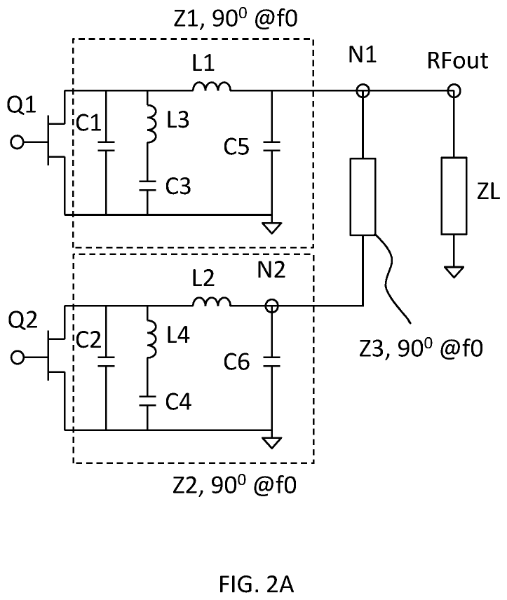

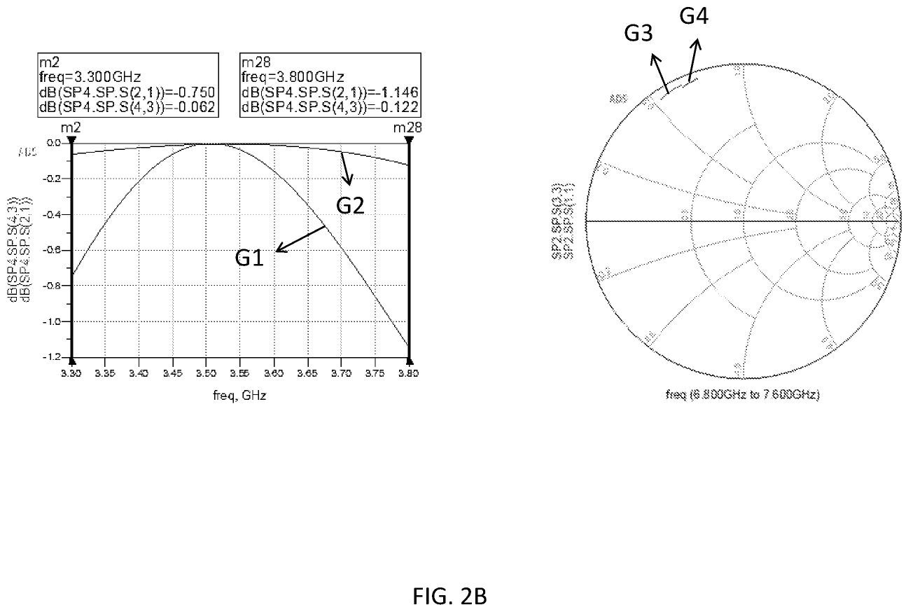

FIG. 2A illustrates an embodiment of a DPA in accordance with the present invention;

FIG. 2B illustrates a comparison in performance of the DPA shown in FIGS. 1 and 2A;

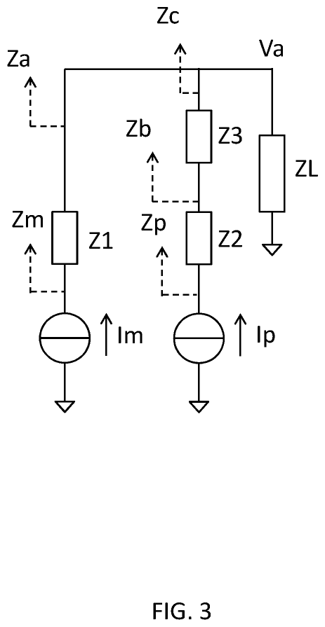

FIG. 3 illustrates a schematic layout of the DPA of FIG. 2A;

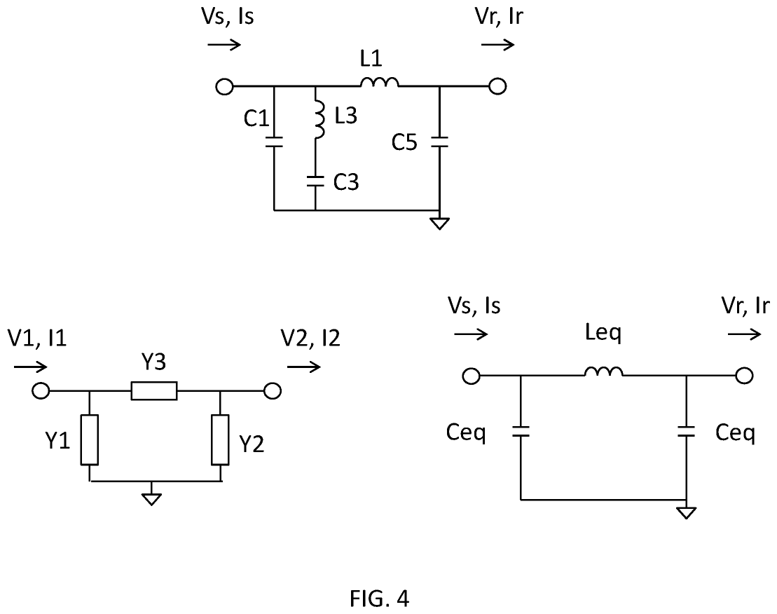

FIG. 4 illustrates how an impedance inverter is formed near the output of the main transistor in the DPA of FIG. 2A;

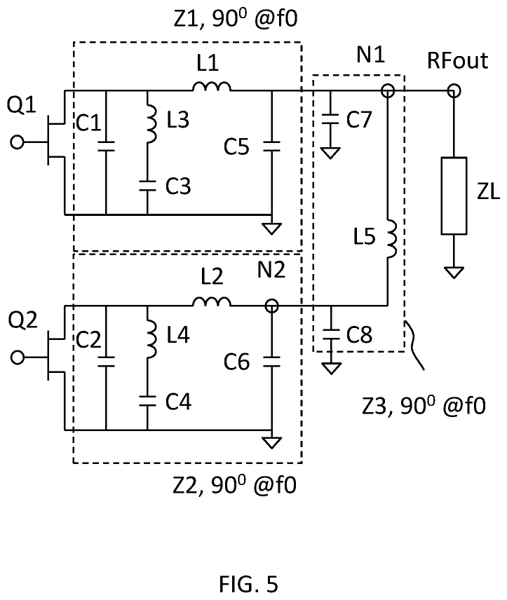

FIG. 5 illustrates a further embodiment of a DPA in accordance with the present invention;

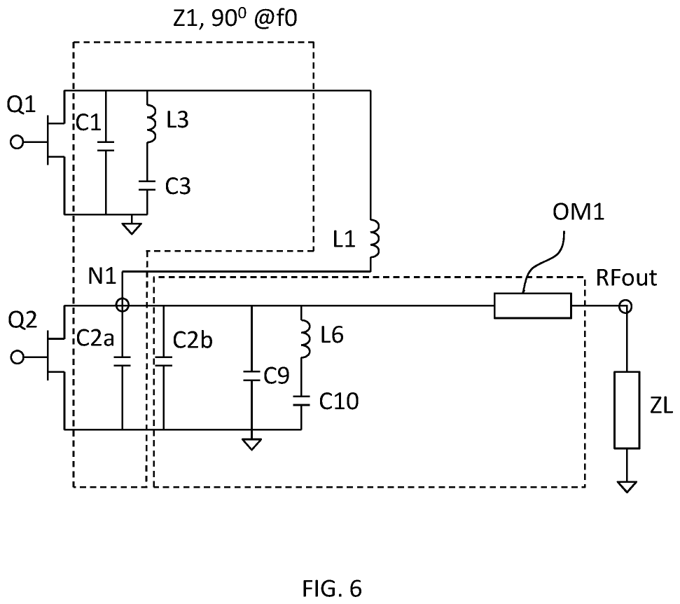

FIG. 6 illustrates an even further embodiment of a DPA in accordance with the present invention;

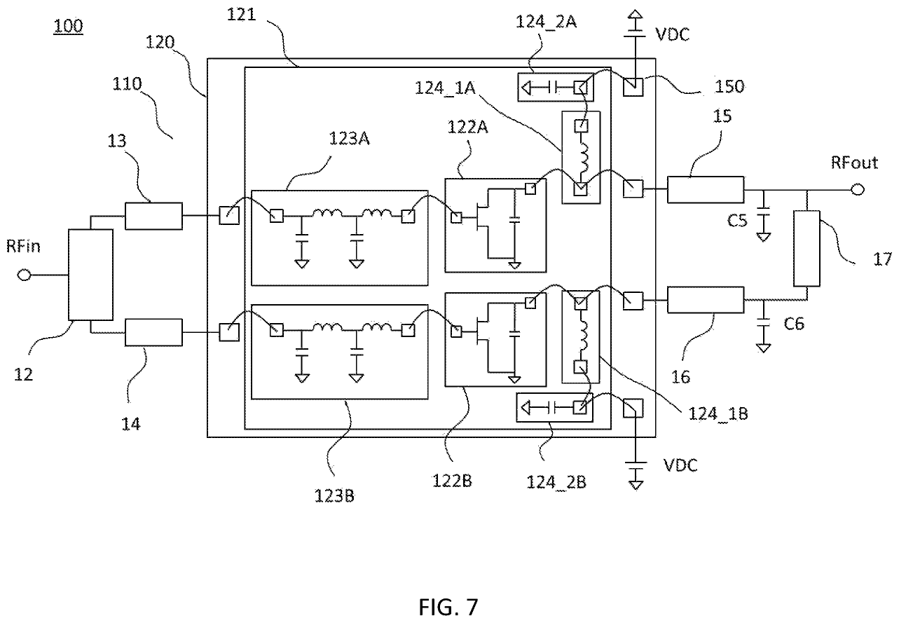

FIGS. 7-10 illustrate various embodiments of an implementation of a DPA in accordance with the present invention.

Hereinafter, a reference to a component, e.g. capacitor C1, and an electrical parameter describing that component, e.g. capacitance C1 of capacitor C1, may be used interchangeably.

FIG. 2A illustrates an embodiment of a DPA in accordance with the present invention. It comprises a main transistor Q1, preferably a GaN HEMT, which has an output capacitance C1. It is connected to a series shunt network of an inductor L3 and a DC decoupling capacitor C3. The DPA further comprises a series inductor L1 that is arranged in between the output of Q1 and combining node N1.

The series shunt network formed by L3 and C3 acts as an inductance at the operational frequency of the DPA, which frequency is typically in the range between 1 and 6 GHz. This effective inductance resonates out part of C1. The remaining part of C1 is substantially equal to the capacitance of capacitor C5. Furthermore, this remaining part of C1, C5, and inductor L1 jointly form a lumped equivalent of a transmission line Z1 having an electrical length of substantially 90 degrees at the operational frequency and having a characteristic impedance Z1.

A similar configuration is used for peak transistor Q2, which is also preferably a GaN HEMT. Here, the series network of L4 and C4, which effectively acts as an inductance at the operational frequency, resonates out part of C2. The remaining part of C2 is substantially equal to the capacitance of capacitor C6. Furthermore, this remaining part of C2, C6, and inductor L2 jointly form a lumped equivalent of a transmission line Z2 having an electrical length of substantially 90 degrees at the operational frequency and having a characteristic impedance Z2. Inductor L2 is arranged in between the output of peak transistor Q2 and intermediate node N2.

A phase delay unit is provided in between intermediate node N2 and combining node N1. In FIG. 2A, this unit is formed using a transmission line Z3 having a characteristic impedance Z3 and having an electrical length that is equal to 90 degrees at the fundamental frequency.

Biasing of Q1, Q2, can be achieved by feeding DC to the node in between L3 and C3, and in between LA and C4. Typically, a choke inductance is arranged in between these nodes and the respective DC sources.

FIG. 2B, left, illustrates a comparison between the S-parameter corresponding to power transferred from the input to the output of the DPA using a topology as shown in FIG. 1 (G1) and a topology as shown in FIG. 2A (G2). As shown, the bandwidth of the topology of FIG. 2A is significantly better than that of FIG. 1. This may be attributed to the compact design in which various transmission lines can be omitted.

FIG. 2B, right, illustrates a comparison between the impedance seen at the output of the main transistor at the second harmonic frequency under low input power conditions using a topology as shown in FIG. 1 (G1) and a topology as shown in FIG. 2A (G2). As shown, with the topology of the present invention it is possible to maintain the same harmonic impedance levels as with the known topology albeit at a better bandwidth.

FIG. 3 illustrates an equivalent circuit for the Doherty power amplifier shown in FIG. 2A when it outputs a target output power Pout_target at fundamental frequency @o. Based on this output power, a parameter Rds_opt can be calculated using:

$$Rds\_opt = \frac{{( Vds , max - Vknee )}^{2}}{2 \times Pout\_target} \qquad Eq . 1$$

where Vds, max is the maximum drain source voltage used, typically corresponding to the supply voltage, and Vknee the knee voltage in the I-V characteristics.

Here, main transistor Q1 is represented by a current source outputting a current Im and peak transistor Q2 by a current source outputting a current Ip. Z1, Z2, and Z3 represent transmission lines having an electrical length equal to 90 degrees at the fundamental frequency and having a characteristic impedance equal to Z1, Z2, Z3, respectively. ZL is the load having an impedance ZL.

The current through ZL equals Im+Ip. The impedance Za seen in the direction shown in FIG. 3 can be computed by dividing the voltage Va by current Im. Voltage Va can be computed using:

$$Va = ( Ip + I m ) ZL \qquad Eq . 1$$

resulting in

$$Za = Va / I m = ZL ( Ip + I m ) / I m = ZL ( 1 + α ) \qquad Eq . 2$$

where α=Ip/Im. Being a 90 degrees transmission line, Z1 transforms impedance Za to an impedance Zm seen at the output of main transistor Q1 according to:

$$Zm = Z {1}^{2} / Za \qquad Eq . 3$$

Main transistor Q1 should be presented with a particular output impedance equal to Rds_main and peak transistor Q2 with a particular output impedance equal to Rds_peak such that a power equal to Pout_target is delivered to load ZL. Assuming that transistors Q1, Q2 are identical other than their sizes, Rds_main can be calculated using:

$$Rds\_main = \frac{{( Vds , max - Vknee )}^{2}}{2 \times Pout\_main} \qquad Eq . 4$$

where Pout_main is the power outputted by main transistor Q1, which can be computed using Pout_main=Im/(Im+Ip)×Pout_target. The power outputted by peak transistor Q2 can be computed using Pout_peak=Ip/(Im+Ip)×Pout_target. Combining this with equation 4 yields:

$$Rds\_main = \frac{{( Vds , max - Vknee )}^{2}}{2 \times Pout\_main} = \frac{{( Vds , max - Vknee )}^{2} ( I m + Ip )}{2 \times I m \times Pout\_target} = Rds\_opt ( 1 + α ) \qquad Eq . 5$$

Combining Eq. 5 with Eq. 2 and Eq. 3 results in:

$$Z 1 = \sqrt{Rds\_main \times Za} = \sqrt{Rds\_opt \times {( 1 + α )}^{2} \times ZL} \qquad Eq . 6$$

In FIG. 3, it is assumed that Z3 does not transform the impedance, hence Zb=Zc. Here, Zc can be computed using:

$$Zc = Va / Ip = ZL ( Ip + I m ) / Ip = ZL ( \frac{α + 1}{α} ) \qquad Eq . 7$$

### Furthermore,

$$Zp = Z {2}^{2} / Zb = Z {2}^{2} / Zc \qquad Eq . 8$$

Similar to Eq. 5, Rds_peak can be found using:

$$Rds\_peak = \frac{{( Vds , max - V knee )}^{2}}{2 \times P out\_peak} = \frac{{( Vds , max - V knee )}^{2} ( I m + Ip )}{2 \times Ip \times P out\_target} = Rds\_opt ( \frac{α + 1}{α} ) \qquad Eq . 9$$

Combining Eq. 9 with Eq. 7 and Eq. 8 results in:

$$Z 2 = \sqrt{Rds\_peak \times Zb} = \sqrt{Rds\_opt \times {( \frac{α + 1}{α} )}^{2} \times Z L} \qquad Eq . 10$$

As Z3 does not transform impedance, its characteristic impedance Z3 equals Zb.

In FIG. 2A, Z1 is realized using a pi-network as shown in FIG. 4 (top), wherein C3 is assumed to act as a RF short. In this figure, L3 resonates out part of C1 such that the remaining part equals C5, thereby resulting in the network shown in FIG. 4 (bottom, right) with Ceq=C5 and Leq=L1.

In general, the ABCD parameters of the pi-network shown in FIG. 4 (bottom, left) can be found using:

$$[ \begin{matrix}V s \\ Is\end{matrix} ] = [ \begin{matrix}A & B \\ C & D\end{matrix} ] [ \begin{matrix}V r \\ Ir\end{matrix} ] = [ \begin{matrix}1 + Y 2 / Y 3 & 1 / Y 3 \\ Y 1 + Y 2 + Y 1 Y 2 / Y 3 & 1 + Y 1 / Y 3\end{matrix} ] \qquad Eq . 11$$

Moreover, the ABCD parameters of a lossless transmission line of length 1 and having characteristic impedance Z0 and real propagation constant β can be found using:

$$[ \begin{matrix}cos β l & jZ 0 sin β l \\ \frac{j}{Z 0} sin β l & cos β l\end{matrix} ] \qquad Eq . 12$$

At fundamental frequency ω₀, βl equals π/2 thereby reducing Eq. 12 to:

$$[ \begin{matrix}0 & jZ 0 \\ j / Z 0 & 0\end{matrix} ] \qquad Eq . 13$$

With Y1=Y2=jωCeq and Y3=1/(jωLeq), taking Z1 as the characteristic impedance, and combining the B parameter at the fundamental frequency of Eq. 11 and Eq. 13, Leq can be found using:

$$j Z 1 = j {ω}_{0} L e q = j {ω}_{0} L 1 \qquad Eq . 14$$

Similarly, Ceq can be found using the C parameter at the fundamental frequency of Eq. 11 and Eq. 13, and combining with Eq. 14:

$$j \frac{1}{Z 1} = 2 j {ω}_{0} C e q + j {ω}_{0} L e q \times - {ω}_{0}^{2} Ce {q}^{2} = 2 j {ω}_{0} C e q - jZ 1 {ω}_{0}^{2} Ce {q}^{2} \qquad Eq . 15$$

Multiplying by jZ1 and re-arranging terms results in:

$$0 = 1 - 2 {ω}_{0} C e q Z 1 + Z {1}^{2} {ω}_{0}^{2} Ce {q}^{2} = {( C e q Z 1 {ω}_{0} - 1 )}^{2} \qquad Eq . 16$$

allowing Ceq to be computed using:

$$C e q = \frac{1}{{ω}_{0} Z 1} = C 5 \qquad Eq . 17$$

Ceq corresponds to the effective capacitance of the network formed by C1, L3, and C3 in FIG. 4 (top). As C3 is a short at RF frequencies, the effective capacitance Ceq at the fundamental frequency is therefore equal to:

$$j {ω}_{0} C e q = j {ω}_{0} C 1 + \frac{1}{j {ω}_{0} L 3} = j {ω}_{0} C 1 ( 1 - \frac{1}{{ω}_{0}^{2} L 3 C 1} ) \qquad Eq . 18$$

Allowing L3 to be computed using:

$$L 3 = \frac{1}{{ω}_{0}^{2} ( C 1 - C e q )} = \frac{1}{{ω}_{0}^{2} ( C 1 - C 5 )} \qquad Eq . 19$$

Similarly, LA, L2, and C6 can be determined using (assuming C4 to be an RF short):

$$C 6 = \frac{1}{{ω}_{0} Z 2} \qquad Eq . 20$$

$$jZ 2 = j {ω}_{0} L 2 \qquad Eq . 21$$

$$L 4 = \frac{1}{{ω}_{0}^{2} ( C 2 - C 6 )} \qquad Eq . 22$$

The impedance seen at the output of main transistor Q1 and peak transistor Q2 at the second harmonic frequency is mostly determined by L3, L1, and C5. More in particular, the impedance of C5 is typically much smaller than the impedance seen looking towards combining node N1.

As demonstrated in Eq. 6 and Eq. 10, both Z1 and Z2 decrease when ZL decreases. This may for example be obtained when an impedance matching network is arranged in between combining node N1 and output terminal RFout. By using such impedance network, the load seen at combining node N1 looking towards load ZL can be lowered. This will result in lower values for Z1, Z2, Z3, L1, L2, L3 and L4. At the same time, C6 and C5 will be increased. As such, the impedance seen at the second harmonic can be changed while still having the same load presented to the main and peak transistors at the fundamental frequency.

In FIG. 5, transmission line Z3 has been replaced by a lumped equivalent comprising shunt capacitors C7, C8 and series inductor L5. Similar to Eq. 14 and Eq. 17, these values can be computed using:

$$Z 3 = {ω}_{0} L 5 \qquad Eq . 23$$

$$\frac{1}{{ω}_{0} Z 3} = C 7 = C 8 \qquad Eq . 24$$

As capacitors C5 and C7 and capacitors C6 and C8 are arranged in parallel, they can be combined into single capacitors.

In an embodiment, the DPA is configured to provide 110 W saturated output power between 3.3 and 3.8 GHz. Assuming a load impedance ZL of 50 Ohms and GaN HEMTs for the main transistor Q1 and peak transistor Q2, typically values would be:

| Component | Value | | Component | Value | |
|---|---|---|---|---|---|
| C1 (parasitic) | 2.1 | pF | C3 | 20 | pF |
| C2 (parasitic) | 3.0 | pF | C4 | 20 | pF |
| L1 | 2.6 | nH | C5 | 0.8 | pF |
| L2 | 1.5 | nH | C6 | 1.4 | pF |
| L3 | 1.7 | nH | C7 | 0.6 | pF |
| L4 | 1.3 | nH | C8 | 0.6 | pF |
| L5 | 3.4 | nH | | | |

In FIG. 6, shunt capacitor C5 of FIGS. 2 and 5 is omitted. Instead, the required capacitance is formed by the network comprising C2, C9, L6 and C10. Typically, either C9 is used in combination with C2 or the series combination of L6 and C10.

In an embodiment, output capacitance C2 can be thought of as having a first component C2a that is part of the lumped equivalent for the 90 degrees transmission line formed together with C1, L3, C3, L1, and a second component C2b that forms part of an output matching network. For this network, L3 and L1 can be computed as define above in Eq. 19 and Eq. 14, respectively. C2a can be computed using

$$C 2 a = \frac{1}{{ω}_{0} Z 1} \qquad Eq . 25$$

In an other embodiment, C2 is smaller than the required capacitance for forming the lumped equivalent. In such cases, for example when the Q2 is smaller than Q1, C9 may provide the additionally required capacitance.

In the embodiments shown in FIGS. 1, 5, and 6, the output part of the Doherty power amplifier was shown. Typically, the Doherty power amplifier comprises a splitter connected to an input of the Doherty power amplifier. This splitter splits an RF signal received at the input into a component to be amplified by the main transistor Q1 and a component to be amplified by the peak transistor Q2. In addition, the signal component to be fed to the peak transistor Q1 is given a phase delay of 90 degrees relative to the signal component to be fed to the main transistor Q2.

In addition, one or more driver stages can be used in between the input terminal of the Doherty power amplifier and main transistor Q1 and peak transistor Q2. Furthermore, one or more impedance matching stages may be provided in between the input terminal of main transistor Q1 and the preceding amplifying stage or one of the outputs of the splitter. Similar impedance matching stages may be provided for the peak transistor Q2.

In FIGS. 6, C9, L6 and C10 are configured to define a suitable impedance at the second harmonic frequency to be presented at the output of peak transistor Q2. Any shift in impedance at the fundamental frequency is corrected using impedance matching network OM1.

FIGS. 7-10 illustrate different embodiments of a Doherty power amplifier comprising a printed circuit board on which a Doherty power amplifier module is mounted. More in particular, FIGS. 7, 8, 9, 10 depict an implementation of the Doherty power amplifiers of FIGS. 2, 2, 5, and 6, respectively.

The Doherty power amplifier module is a packaged device comprising a substrate on which several components and semiconductor dies are mounted. The module in FIGS. 7-10 is formed using conventional packaging technologies. For example, the module may be a flat no-leads package, such as dual flat no-leads, DFN, or a quad flat no-leads QFN, package.

FIG. 7 illustrates an implementation of the Doherty power amplifier of FIG. 2A. More in particular, FIG. 7 illustrates a DPA 100 comprising a Doherty power amplifier module 120 that is mounted on a printed circuit board 110. Doherty power amplifier module 120 comprises a substrate 121 on which are mounted a first GaN die 122A and a second GaN die 122B. GaN die 122A comprises main transistor Q1, and GaN die 122B comprises peak transistor Q2. In other embodiments, a single GaN die can be used on which both main transistor Q1 and peak transistor Q2 are provided.

Substrate 121 is in the form of a central conductive pad, made for example from copper. Substrate 121 may not only provide sufficient cooling capability but may also serve as an electrical ground. Electrical connection to module 120 is made possible through central pad 121 and a plurality of pads 150, which pads 150 are exposed on a backside of module 120. Similar pads are arranged on printed circuit board 110. Connection is achieved by connecting the pads of module 120 with corresponding pads on printed circuit board 110.

In case a leadframe technology is used, substrate 121 may also be conductive. In addition, a plurality of leads is used, spaced apart from substrate 121, for inputting and outputting electrical signals to and from module 120.

Module 120 comprises a first passive die 123A and a second passive die 123B that are mounted on substrate 121. Passive dies 123A, 123B can for example comprise Si dies. On dies 123A, 123B, respective impedance matching networks are integrated that each comprise a plurality of shunt capacitors and series inductors. The matching networks shown in FIG. 7 correspond to two-stage low pass matching networks. The outputs of dies 123A, 123B are connected to the inputs of Q1, Q2, using respective bondwirbes. The inputs of dies 123A, 123B are electrically connected to pads 150 of module 120.

The output of main transistor Q1 is connected, via a bondwire, to a further passive die 124_1A, such as a ceramic die, on which L3 is integrated. Similarly, the output of peak transistor Q2 is connected, via a bondwire, to a further passive die 124_1B, such as a ceramic die, on which LA is integrated. DC decoupling capacitors C3, C4 are realized on separate passive dies 124_2A, 124_2B, respectively, which are also mounted on substrate 121. Dies 124_1A, 124_1B are connected to dies 124_2A, 124_2B, respectively, using one or more bondwires. Furthermore, dies 124_1A, 124_1B, 124_2A, 124_2B are mounted on substrate 121. Dies 124_1A, 124_2A, 124_1B, 124_2B are connected, using one or more bondwires, to pads 150 of module 120. Pads 150 are exposed on a backside of module 120. Similar pads (not shown) are provided on printed circuit board 110 allowing electrical contact between printed circuit board 110 and module 120. Substrate 121 comprises a central ground pad to allow grounding of main transistor Q1 and peak transistor Q2.

L3 is connected to a pad of module 120 using one or more bondwires. This pad is connected via a transmission line 15 to a shunt capacitor C5. Here, transmission line 15 at least partially forms series inductor L1. Similarly, L4 is connected to a pad of module 120 using one or more bondwires. This pad is connected via a transmission line 16 to a shunt capacitor C6. Here, transmission line 16 at least partially forms series inductor L2. Transmission line 16 is connected to a further transmission line 17 that is arranged in between transmission line 16 and output terminal RFout. Transmission line 17 corresponds to phase delay unit Z3 in FIG. 2A and forms a 90 degrees transmission line at the fundamental frequency.

At the input side, DPA 100 comprises a splitter 12 that is connected to input terminal RFin. Splitter 12 splits the RF signal received at input terminal RFin into a component to be fed to Q1 and a component to be fed to Q2. One output of splitter 12 is connected via a transmission line 13 to the terminal of module 120 that is connected to the input of the matching network on passive die 123A. Similarly, the other output of splitter 12 is connected via a transmission line 14 to the terminal of module 120 that is connected to the input of the matching network on passive die 123B.

Biasing of Q1 and Q2 at the output side can be achieved by connecting a DC source VDC to the node in between L3 and C3, and between LA and C4. Typically, choke inductors are arranged in series with VDC to prevent RF signal from entering the DC source.

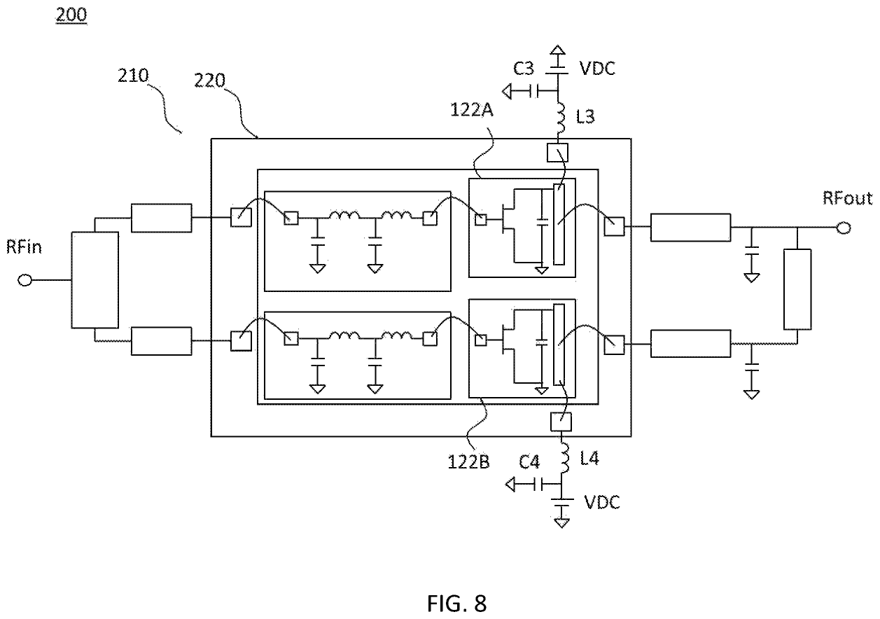

FIG. 8 is also an implementation of the DPA of FIG. 2A. DPA 200 differs from DPA 100 shown in FIG. 7 in that inductors L3, LA and DC decoupling capacitors C3, C4 are arranged on printed circuit board 210, thereby reducing the size of module 220.

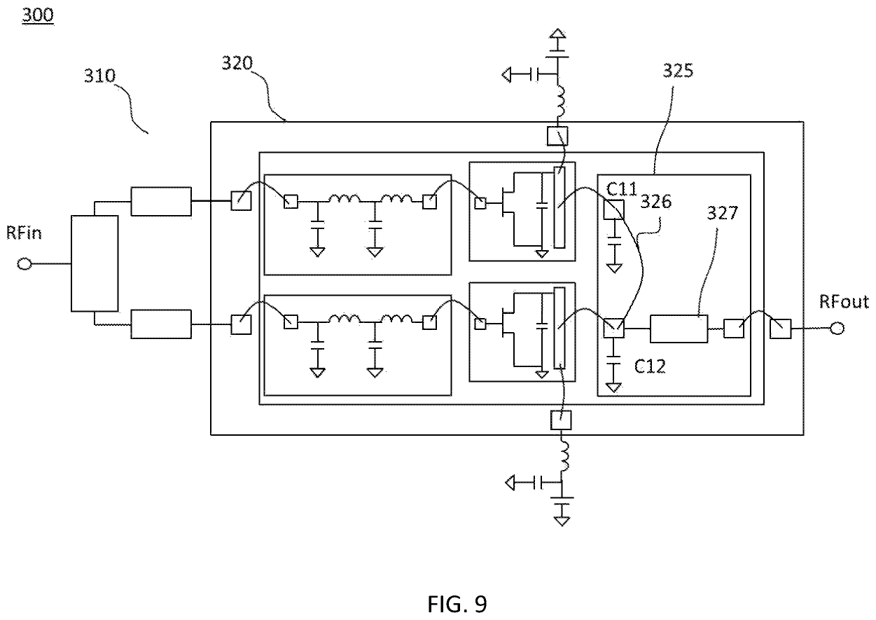

FIG. 9 illustrates a DPA 300 that is an implementation of the DPA shown in FIG. 5. Module 320, which is mounted on printed circuit board 310, comprises a passive die 325 on which two capacitors C11, C12 are arranged. Capacitor C11 corresponds to the combination of C5 and C7 in FIG. 5, and capacitor C12 to the combination of C6 and C8 in FIG. 5. One or more bondwires 326 connect capacitors C11, C12 and form inductor L5 of FIG. 5. Furthermore, the one or more bondwires connecting the output of Q1 to capacitor C11 forms inductor L1 of FIG. 5, and the one or more bondwires connecting the output of Q2 to capacitor C12 forms inductor L2 of FIG. 5. An impedance matching network 327 connects a terminal of C11 to output terminal RFout.

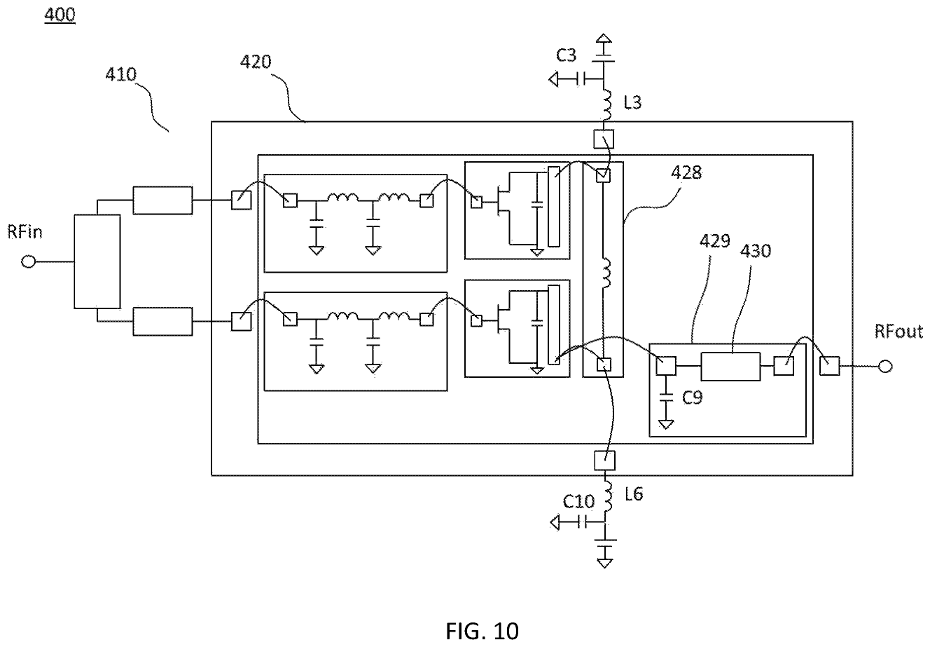

FIG. 10 illustrates a DPA 400 that is an implementation of the DPA shown in FIG. 6. Here, a passive die 428 of module 420 comprising a transmission line or other inductive element is used for forming, together with the bondwires connecting the inductive element to Q1, Q2, inductor L1 of FIG. 6. Instead of the inductive element shown in FIG. 6, a bondwire extending between the outputs of Q1, Q2 may equally be used. Furthermore, L3 and C3 may also be connected to the output of Q1 instead of to the inductive element on passive die 428.

A passive die 429 is used on which an impedance matching network 430 is integrated. In addition, a capacitor can be integrated on passive die 429 that corresponds to capacitor C9 of FIG. 6. Additionally or alternatively, an inductor corresponding to inductor L6 of FIG. 6 and a capacitor corresponding to capacitor C10 may be integrated on printed circuit board 410.

In the above, the present invention has been explained using detailed embodiments thereof. However, the present invention is not limited to these embodiments and various modifications are possible without deviating from the scope of the present invention which is defined by the appended claims.

1. A Doherty power amplifier, comprising:
an output terminal connectable or connected to a load;
a main transistor having a first output capacitance;
a peak transistor having a second output capacitance, wherein the main transistor and the peak transistor each comprise a Gallium Nitride based high electron mobility transistor;
a first shunt network arranged in between an output of the main transistor and ground, the first shunt network comprising a series connection of a first shunt inductor and a first shunt DC decoupling capacitor;
a first series inductor arranged in between the output of the main transistor and a combining node, wherein the combining node is electrically connected to the output terminal either directly or indirectly via an impedance matching network, and wherein the Doherty power amplifier is configured to combine signals amplified by the main transistor and the peak transistor at the combining node; and
a first shunt capacitive element arranged in between the combining node and ground,
wherein an inductance of the first shunt network is configured such that the first shunt network resonates with a part of the first output capacitance at a given frequency within an operational frequency band of the Doherty power amplifier, wherein a remaining part of the first output capacitance forms, together with the first series inductor and at least a part of the first shunt capacitive element, an impedance inverter at said given frequency,
wherein the impedance inverter is a first lumped equivalent of a transmission line having an electrical length of substantially 90 degrees at said given frequency,
the Doherty power amplifier further comprising:
a second shunt network arranged in between an output of the peak transistor and ground, the second shunt network comprising a series connection of a second shunt inductor and a second shunt DC decoupling capacitor;
a second series inductor arranged in between the output of the peak transistor and an intermediate node;
a phase delay unit connected in between the intermediate node and the combining node; and
a second shunt capacitive element arranged in between the intermediate node and ground,
wherein an inductance of the second shunt network is configured such that the second shunt network resonates with a part of the second output capacitance at said given frequency, wherein a remaining part of the second output capacitance forms, together with the second series inductor and at least a part of the second shunt capacitive element, a second lumped equivalent of a transmission line at said given frequency,
wherein a combined phase delay associated with the second lumped equivalent and the phase delay unit substantially equals 180 degrees at said given frequency, and
wherein the second lumped equivalent is a lumped equivalent of a transmission line having an electrical length of substantially 90 degrees at said given frequency.

2. The Doherty power amplifier according to claim 1, wherein the phase delay unit comprises:
a third series inductor arranged in between the intermediate node and the combining node;
a third shunt capacitive element arranged in between the combining node and ground; and
a fourth shunt capacitive element arranged in between the intermediate node and ground.

3. The Doherty power amplifier according to claim 1, wherein the combining node is electrically connected to the output terminal indirectly via an impedance matching network, and wherein the impedance matching network is configured to lower the impedance seen at the combining node looking towards load relative to said load.

4. The Doherty power amplifier according to claim 1, wherein the third shunt capacitive element and the first shunt capacitive element are embodied as a single shunt capacitor, and/or wherein the fourth shunt capacitive element and the second shunt capacitive element are embodied as a single shunt capacitor.

5. The Doherty power amplifier according to claim 1, further comprising a first low-pass input impedance matching network connected to an input of the main transistor and a second low-pass input impedance matching network connected to an input of the peak transistor.

6. The Doherty power amplifier according to claim 5, wherein the first and second low-pass input impedance matching networks each comprise one or more matching stages, each matching stage comprising a shunt inductor and a series inductor.

7. The Doherty power amplifier according to claim 1, further comprising:
an input terminal; and
a splitter configured for splitting an RF signal received at the input terminal into a first component to be fed to the main transistor and a second component to be fed to the peak transistor.

8. The Doherty power amplifier according to claim 1, comprising:
a printer circuit board;
a packaged Doherty power amplifier module mounted on the printed circuit board, wherein the module comprises:
a substrate;
a first active semiconductor die mounted on the substrate and on which the main transistor is integrated; and
a second active semiconductor die mounted on the substrate and on which the peak transistor is integrated.

9. The Doherty power amplifier according to claim 8, wherein the module corresponds to a flat no-leads package, such as a dual flat no-leads package, DFN, or a quad flat no-leads package, QFN, wherein the substrate is formed by a conductive central pad that is exposed on a backside of the package, and wherein the module further comprises a plurality of pads that are spaced apart from the central pad and that are exposed on the backside of the package.

10. The Doherty power amplifier according to claim 8, wherein the module comprises one or more first passive dies on which a first impedance matching network is integrated of which an output is connected to an input of the main transistor, and on which a second impedance matching network is integrated of which an output is connected to an input of the peak transistor.

11. The Doherty power amplifier according to claim 8, wherein the first shunt inductor and the first shunt DC decoupling capacitor are integrated on the printed circuit board, and/or
wherein the combining node is electrically connected to the output terminal indirectly via an impedance matching network, wherein the impedance matching network is configured to lower the impedance seen at the combining node looking towards load relative to said load, and wherein the second shunt inductor and the second shunt DC decoupling capacitor are integrated on the printed circuit board.

12. The Doherty power amplifier according to claim 8, wherein the module comprises one or more second passive dies on which the first shunt inductor and the first shunt DC decoupling capacitor are integrated, and/or, on which the second shunt inductor and the second shunt DC decoupling capacitor are integrated.

13. The Doherty power amplifier according to claim 8, further comprising a first transmission line or lumped equivalent thereof integrated on or formed on the printed circuit board, the first transmission line forming at least a part of the first series inductor, wherein the first shunt capacitive element is integrated on or formed on the printed circuit board.

14. The Doherty power amplifier according to claim 8, further comprising a second transmission line or lumped equivalent thereof integrated on or formed on the printed circuit board, the second transmission line forming at least a part of the second series inductor, wherein the second shunt capacitive element is integrated on or formed on the printed circuit board.

15. The Doherty power amplifier according to claim 8, further comprising a third passive die on which the phase delay unit is integrated, the phase delay unit comprising a transmission line or lumped equivalent thereof, the third passive die preferably comprising an impedance matching network connected between the combining node and the output terminal.

16. The Doherty power amplifier according to claim 15, wherein the first series inductor is formed using one or more bondwires between the output of the main transistor and a terminal of phase delay unit, and/or wherein the second series inductor is formed using one or more bondwires between the output of the peak transistor and an other terminal of phase delay unit.

17. The Doherty power amplifier according to claim 7, wherein the splitter is integrated or formed on the printed circuit board.

18. The Doherty power amplifier according to claim 1, further comprising:
a main driver stage arranged in between the splitter and the main transistor and on the substrate, the main driver stage being configured for amplifying the signal to be fed to the main transistor and for providing this amplified signal to the main transistor; and/or
a peak driver stage arranged in between the splitter and the peak transistor and on the substrate, the peak driver stage being configured for amplifying the signal to be fed to the peak transistor and for providing this amplified signal to the peak transistor.

19. A packaged Doherty power amplifier module as defined in claim 8 and configured to be mounted on a printed circuit board for forming the Doherty power amplifier according to any of the previous claims.
